(19) United States
(12) Patent Application Publication
(10) Pub. No.: US 2025/0294835 A1
(43) Pub. Date: Sep. 18, 2025

(54) ELONGATED VERTICAL STRUCTURES OF CHANNEL MATERIALS

(71) Applicant: Intel Corporation, Santa Clara, CA (US)

(72) Inventors: Abhishek A. Sharma, Portland, OR (US); Wilfred Gomes, Portland, OR (US); Tahir Ghani, Portland, OR (US); Anand S. Murthy, Portland, OR (US)

(73) Assignee: Intel Corporation, Santa Clara, CA (US)

(21) Appl. No.: 18/603,303

(22) Filed: Mar. 13, 2024

(51) Int. Cl. H01L 29/10; H01L 21/3213; H01L 29/04

(52) U.S. Cl. CPC H10D 62/314; H01L 21/32137; H10D 62/405

(57) ABSTRACT

Methods for fabricating integrated circuit (IC) structures with elongated vertical structures of channel materials, as well as associated IC structures, are disclosed. In one aspect, an IC structure includes a substrate and a pillar of a semiconductor material perpendicular to the substrate, where, in a cross-section of the pillar along a plane perpendicular to the substrate, the pillar tapers away from the substrate. In another aspect, an IC structure includes a substrate, one or more materials over the substrate, and an opening extending through the one or more materials to the substrate, wherein a portion of the substrate forms the bottom of the opening. The IC structure further includes a semiconductor material in the opening, wherein a crystal lattice/grain orientation of the semiconductor material is substantially same as a crystal lattice/grain orientation of the portion of the substrate at the bottom of the opening.

### BACKGROUND

For the past several decades, the scaling of features in integrated circuits (ICs) has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize the performance of each device and each contact becomes increasingly significant. Careful design of transistors may help with such an optimization.

### BRIEF DESCRIPTION OF THE DRAWINGS

Embodiments will be readily understood by the following detailed description in conjunction with the accompanying drawings.

FIG. 1 is a flow diagram of a first method for fabricating IC structures with elongated vertical structures of channel materials, according to some embodiments.

FIGS. 2A-2J illustrate example results at various stages in the fabrication of an IC structure using the method of FIG. 1, according to some embodiments.

FIGS. 3A-3E provide cross-sectional side views of pillars with different sidewall profiles that may be realized using the method of FIG. 1, according to some embodiments.

FIG. 4 is a flow diagram of a second method for fabricating IC structures with elongated vertical structures of channel materials, according to some embodiments.

FIGS. 5A-5E illustrate example results at various stages in the fabrication of an IC structure using the method of FIG. 4, according to some embodiments.

FIGS. 6A-6B illustrate alternative IC structures that may be realized using the method of FIG. 4, according to some embodiments.

FIG. 7 provides top views of a wafer and dies that may include one or more IC structures with elongated vertical structures of channel materials in accordance with any of the embodiments disclosed herein.

FIG. 8 is a cross-sectional side view of an IC package that may include one or more IC structures with elongated vertical structures of channel materials in accordance with any of the embodiments disclosed herein.

FIG. 9 is a cross-sectional side view of an IC device assembly that may include one or more IC structures with elongated vertical structures of channel materials in accordance with any of the embodiments disclosed herein.

FIG. 10 is a block diagram of an example computing device that may include one or more IC structures with elongated vertical structures of channel materials in accordance with any of the embodiments disclosed herein.

FIG. 11 is a block diagram of an example processing device that may include one or more IC structures with elongated vertical structures of channel materials in accordance with any of the embodiments disclosed herein.

### DETAILED DESCRIPTION

Conventional transistors are formed in a device layer on a semiconductor substrate, at the “front end” of a manufacturing process, where a channel material of a transistor is typically a part of the semiconductor substrate and is oriented horizontally (e.g., substantially parallel to the substrate). Such conventional transistors have been limited in their scalability in some applications (e.g., in some memory applications). Disclosed herein are methods for fabricating IC structures with elongated vertical structures of channel materials, as well as associated IC structures, devices, and systems. In one aspect, an IC structure includes a substrate and a pillar of a semiconductor material perpendicular to the substrate. Such a pillar is one example of an elongated vertical structure of a channel material (e.g., the semiconductor material of the pillar) for one or more transistors. In a cross-section of the pillar along a plane perpendicular to the substrate, the pillar tapers (e.g., the width of the pillar gradually decreases) away from the substrate. For example, the pillar may include a first end and an opposite second end, wherein the first end is wider than the second end and is closer to the substrate than the second end. In another aspect, an IC structure includes a substrate, one or more materials over the substrate, and an opening extending through the one or more materials to the substrate, wherein a portion of the substrate forms the bottom of the opening. The IC structure further includes a semiconductor material in the opening, wherein a crystal lattice orientation of the semiconductor material is substantially same as a crystal lattice orientation of the portion of the substrate at the bottom of the opening, and/or wherein a grain orientation of a majority of grains of the semiconductor material is substantially same as a grain orientation of a majority of grains of the portion of the substrate at the bottom of the opening. Such a semiconductor material in the opening is another example of an elongated vertical structure of a channel material (e.g., the semiconductor material of the opening) for one or more transistors. IC structures with elongated vertical structures of channel materials as described herein may be used to address the scaling challenges of conventional transistor architectures and enable high density device arrangements compatible with advanced complementary metal-oxide-semiconductor (CMOS) processes. Other technical effects will be evident from various embodiments described here.

In the following detailed description, various aspects of the illustrative implementations may be described using terms commonly employed by those skilled in the art to convey the substance of their work to others skilled in the art. For example, as used herein, the term “channel material” refers to one or more semiconductor materials in which a channel of a transistor is formed during operation, with source and drain (S/D) regions of a transistor provided on either side of the channel material. In another example, in context of S/D regions of transistors, the term “region” may be used interchangeably with the terms “contact” and “terminal” of a transistor. As used herein, the term “connected” may mean a direct electrical or magnetic connection between the things that are connected, without any intermediary devices, while the term “coupled” may mean either a direct electrical or magnetic connection between the things that are connected, or an indirect connection through one or more passive or active intermediary devices. As used herein, A connected to B may include A being in physical contact (e.g., in direct physical contact) with B; if one or more interfacial layers may form when A and B are brought into direct physical contact, then such interfacial layers may be considered to be a part of A and/or a part of B. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−20%, e.g., within +/−5% or within +/−2% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

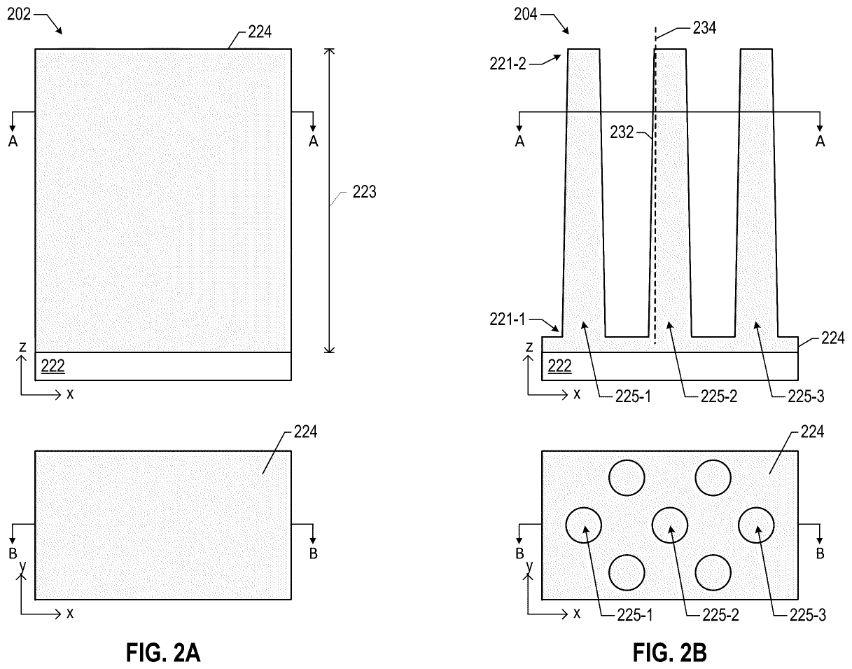

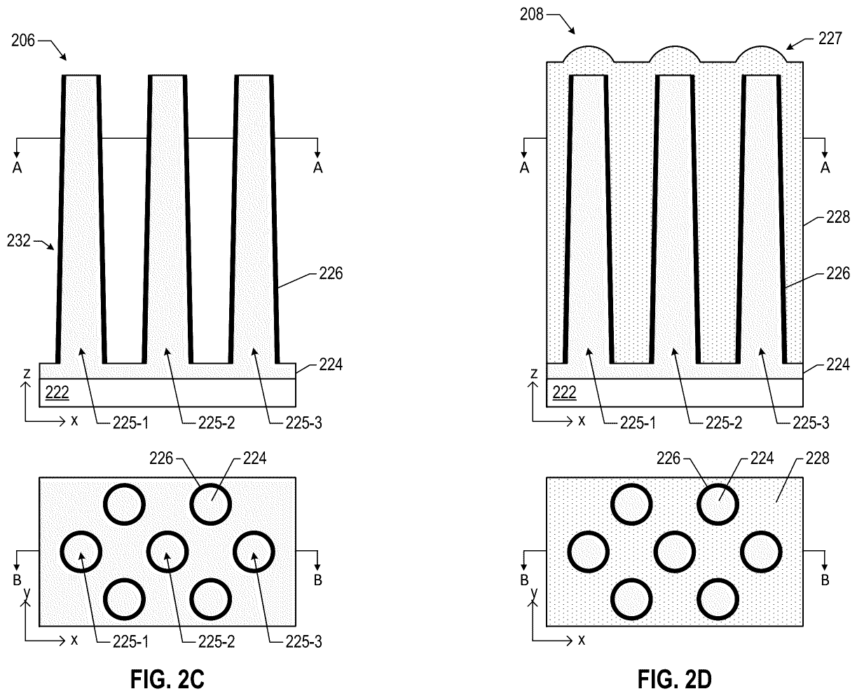

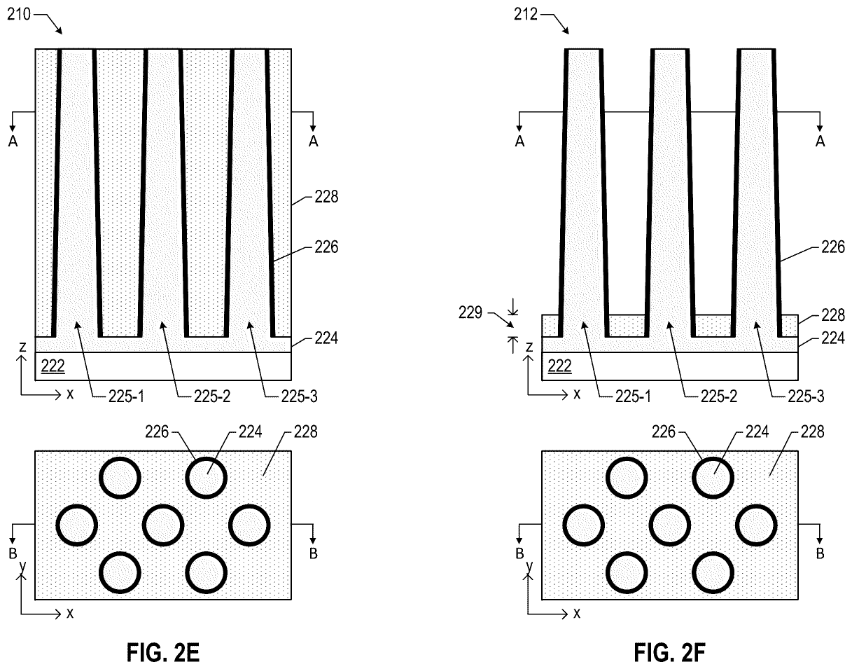

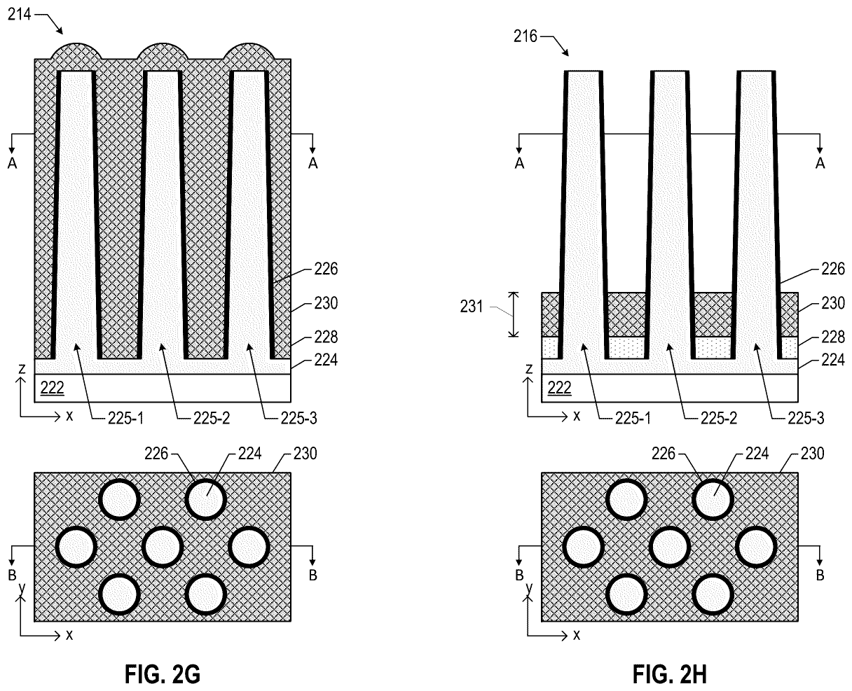

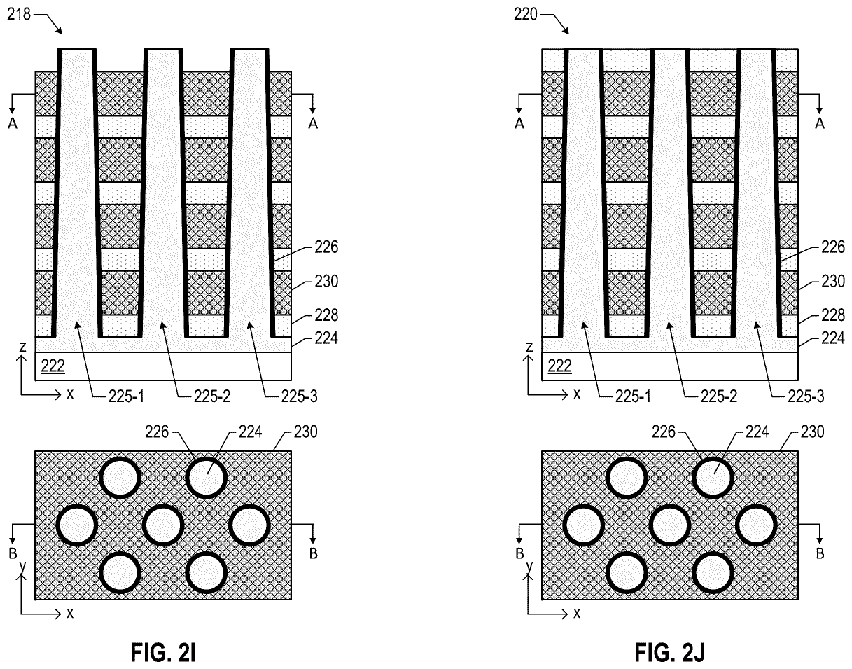

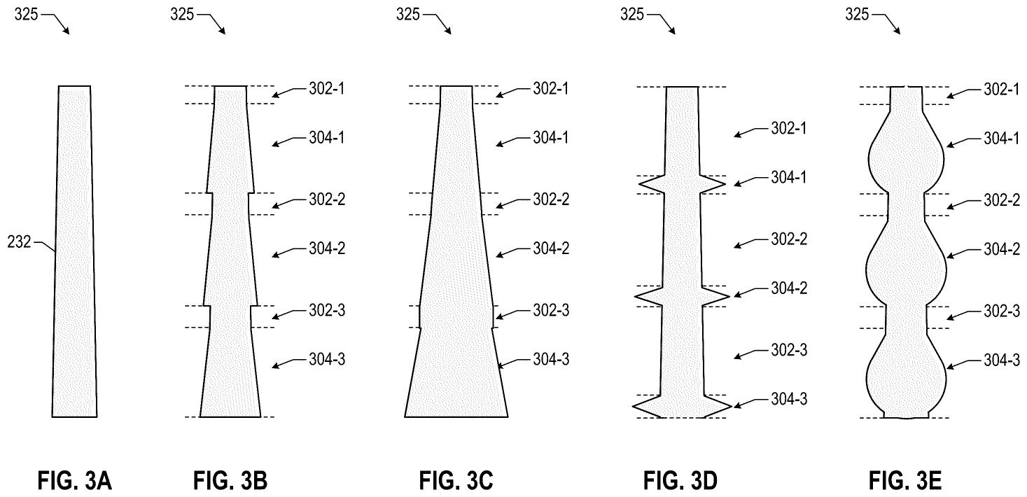

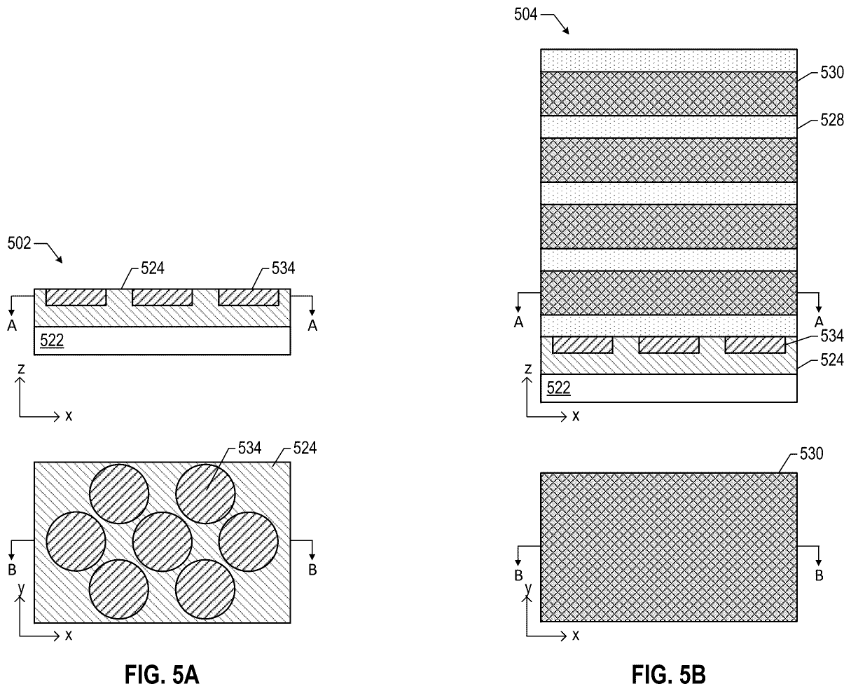

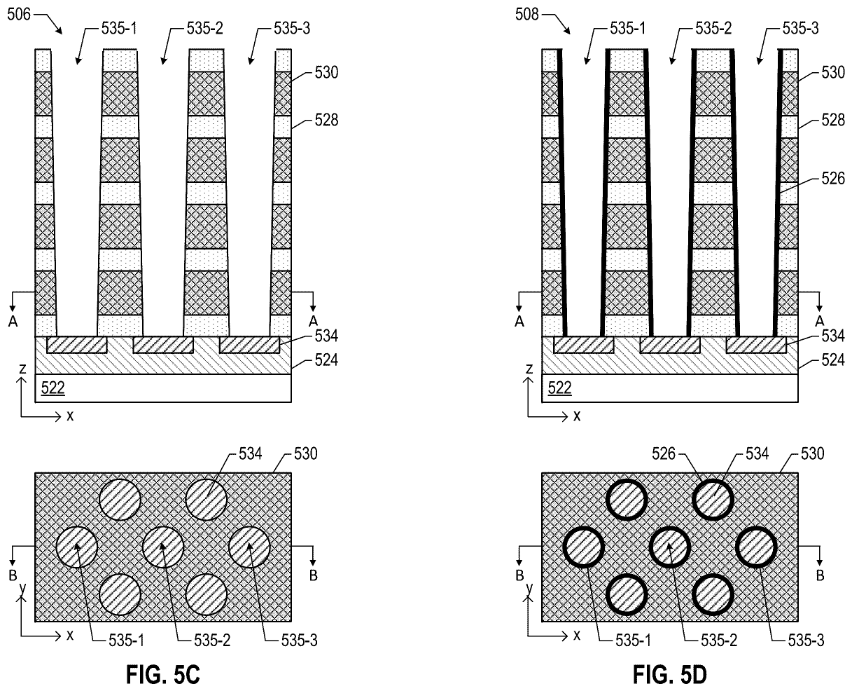

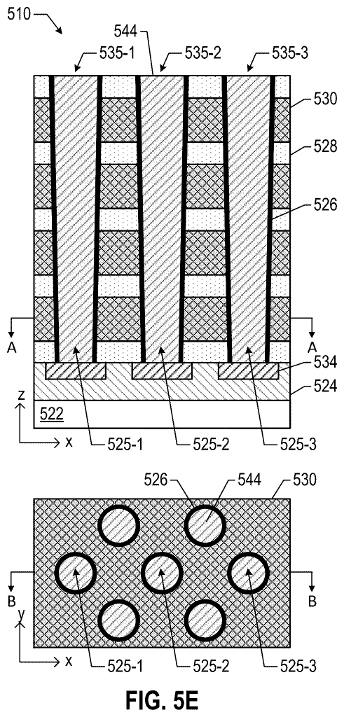

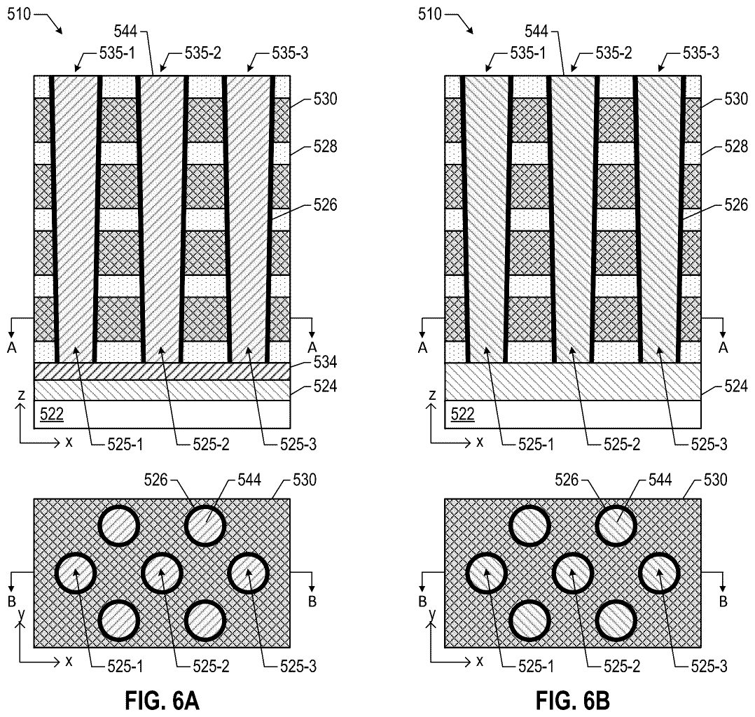

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. For convenience, analogous elements designated in the present drawings with different reference numerals after a dash, e.g., pillars 225-1, 225-2, and 225-3 may be referred to together without the reference numerals after the dash, e.g., as “pillars 225.” In order to not clutter the drawings, if multiple instances of certain elements are illustrated, only some of the elements may be labeled with a reference sign. For convenience, the phrase “FIG. 2” may be used to refer to the collection of drawings of FIGS. 2A-2J, the phrase “FIG. 3” may be used to refer to the collection of drawings of FIGS. 3A-3E, the phrase “FIG. 5” may be used to refer to the collection of drawings of FIGS. 5A-5E, and the phrase “FIG. 6” may be used to refer to the collection of drawings of FIGS. 6A-6B.

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of IC structures with elongated vertical structures of channel materials as described herein.

Various IC structures with elongated vertical structures of channel materials as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

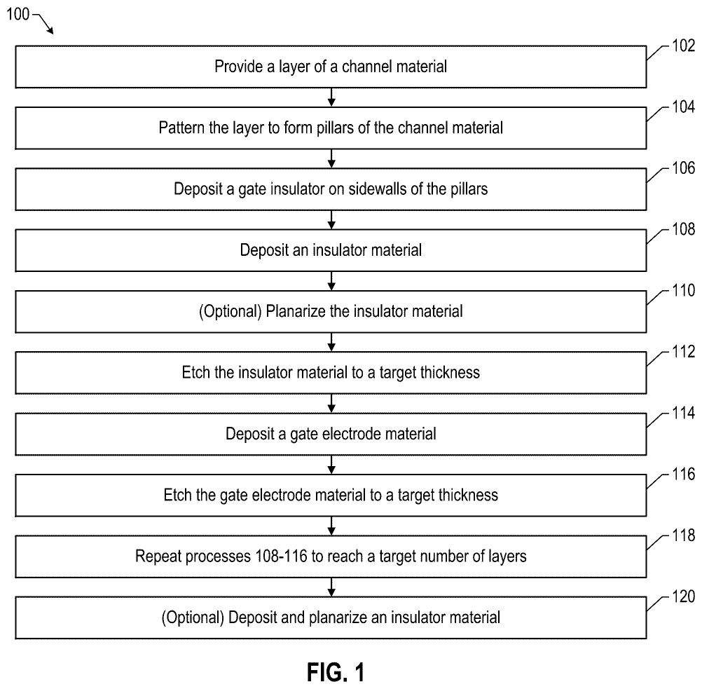

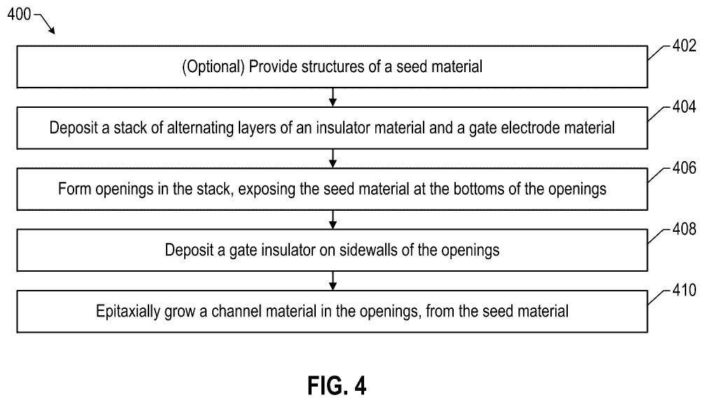

FIG. 1 is a flow diagram of a first method, a method 100, for fabricating IC structures with elongated vertical structures of channel materials, according to some embodiments, while FIGS. 2A-2J illustrate example results at various stages in the fabrication of an IC structure using the method 100 and FIGS. 3A-3E illustrate some further variations that may result from using the method 100, according to some embodiments. Similarly, FIG. 4 is a flow diagram of a second method, a method 400, for fabricating IC structures with elongated vertical structures of channel materials, according to some embodiments, while FIGS. 5A-5E illustrate example results at various stages in the fabrication of an IC structure using the method 400 and FIGS. 6A-6B illustrate some further variations that may result from using the method 400, according to some embodiments. In particular, each of FIGS. 2A-2J, FIGS. 3A-3E, FIGS. 5A-5E, and FIGS. 6A-6B illustrates a cross-sectional side view (a cross-section in an x-z plane of an example coordinate system assumed for all of the present drawings indicating a coordinate system) and a corresponding top-down view (a cross-section in an x-y plane of the example coordinate system) of an IC structure, where the top-down view is a view along a plane AA shown in the cross-sectional side view of these drawings, and the cross-sectional side view is a view along a cross-section of a plane BB shown in the top-down view of these drawings.

Although the operations of the methods 100 and 400 are illustrated once each and in a particular order, the operations may be performed in any suitable order and repeated as desired. For example, one or more operations may be performed in parallel to fabricate multiple IC structures with elongated vertical structures of channel materials substantially simultaneously. In another example, the operations may be performed in a different order to reflect the structure of an IC device in which one or more IC structures with elongated vertical structures of channel materials will be implemented.

In addition, the example methods 100 and 400 may include other operations not specifically shown in the present drawings, such as various cleaning or planarization operations as known in the art. For example, in some embodiments, the top layers of any of the IC structures may be cleaned prior to, after, or during any of the processes of the methods 100 and 400 described herein, e.g., to remove oxides, surface-bound organic and metallic contaminants, as well as subsurface contamination. In some embodiments, cleaning may be carried out using e.g., a chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, IC structures described herein may be planarized prior to, after, or during any of the processes of the methods 100 and 400 described herein, e.g., to remove overburden or excess materials.

Turning to the first method, as shown in FIG. 1, the method 100 may begin with a process 102 that includes providing a layer of a channel material over a support. An IC structure 202 of FIG. 2A illustrates an example result of the process 102. As shown in FIG. 2A, the IC structure 202 illustrates a support 222 and a layer of a channel material 224 over the support 222.

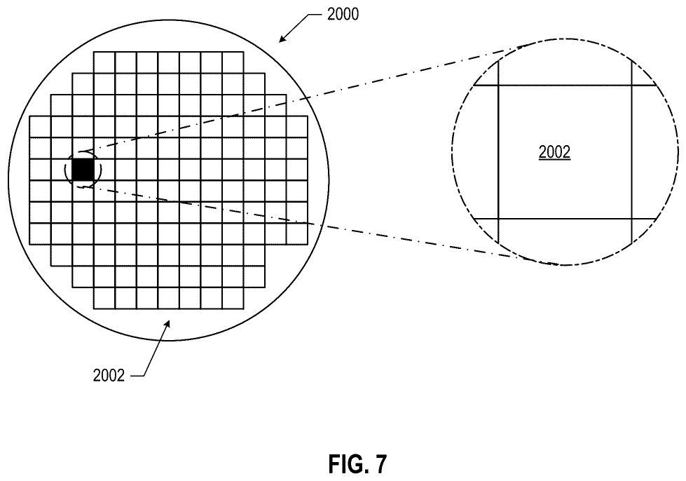

The support 222 may include any suitable support structure, such as a substrate, a die, a wafer, or a chip, on which elongated vertical structures of channel materials may be built. The support 222 may, e.g., be the wafer 2000 of FIG. 7, discussed below, and may be, or be included in, a die, e.g., the singulated die 2002 of FIG. 7, discussed below. The support 222 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support 222 may be a printed circuit board (PCB) substrate, a package substrate, an interposer, a wafer, or a die. Although a few examples of materials from which the support 222 may be formed are described here, any material that may serve as a foundation upon which one or more IC structures with elongated vertical structures of channel materials as described herein may be built falls within the spirit and scope of the present disclosure.

In general, the channel material 224 may be composed of semiconductor material systems including, for example, N-type or P-type materials systems. In some embodiments, the channel material 224 may include a substantially monocrystalline semiconductor, such as silicon (Si) or germanium (Ge). In some embodiments, the channel material 224 may include a compound semiconductor with a first sub-lattice of at least one element from group III of the periodic table (e.g., Al, Ga, In), and a second sub-lattice of at least one element of group V of the periodic table (e.g., P, As, Sb). In some embodiments, the channel material 224 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material 224 may include a combination of semiconductor materials.

For some example N-type transistor embodiments (i.e., for the embodiments where a transistor having a channel portion as a part of the channel material 224 is included is an N-type metal-oxide-semiconductor (NMOS) transistor), the channel material 224 may include a III-V material having a relatively high electron mobility, such as, but not limited to InGaAs, InP, InSb, and InAs. For some such embodiments, the channel material 224 may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). For some example P-type transistor embodiments (i.e., for the embodiments where a transistor having a channel portion as a part of the channel material 224 is included is a P-type metal-oxide-semiconductor (PMOS) transistor), the channel material 224 may advantageously be a group IV material having a high hole mobility, such as, but not limited to Ge or a Ge-rich SiGe alloy. For some example embodiments, the channel material 224 may have a Ge content between 0.6 and 0.9, and advantageously may be at least 0.7.

In some embodiments, the channel material 224 may be a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the channel material 224 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc.

As noted above, the channel material 224 may include IGZO. IGZO-based devices have several desirable electrical and manufacturing properties. IGZO has high electron mobility compared to other semiconductors, e.g., in the range of 20-50 times than amorphous silicon. Furthermore, amorphous IGZO (a-IGZO) transistors are typically characterized by high band gaps, low-temperature process compatibility, and low fabrication cost relative to other semiconductors. IGZO can be deposited as a uniform amorphous phase while retaining higher carrier mobility than oxide semiconductors such as zinc oxide. Different formulations of IGZO include different ratios of indium oxide, gallium oxide, and zinc oxide. One particular form of IGZO has the chemical formula InGaO₃(ZnO)₅. Another example form of IGZO has an indium:gallium:zinc ratio of 1:2:1. In various other examples, IGZO may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10). IGZO can also contain tertiary dopants such as aluminum or nitrogen.

In some embodiments, a transistor having a channel portion as a part of the channel material 224 may be a thin-film transistor (TFT). A TFT is a special kind of a field-effect transistor (FET) made by depositing a thin film of an active semiconductor material over a support (e.g., a support structure as described above) that may be a non-conducting support. Some such materials may be deposited at relatively low temperatures, which allows depositing them within the thermal budgets imposed on back-end fabrication to avoid damaging the front-end components such as the logic devices of an IC structure in which the channel material 224 may be included. At least a portion of the active semiconductor material forms a channel of the TFT. In some such embodiments, the channel material 224 may be deposited as a semiconductor material deposited at relatively low temperatures and may include any of the oxide semiconductor materials described above.

In other embodiments, instead of being deposited at relatively low temperatures as described above with reference to the TFTs, the channel material 224 may be epitaxially grown in what typically involves relatively high-temperature processing. In such embodiments, the channel material 224 may include any of the semiconductor materials described above, including oxide semiconductor materials. In some such embodiments, the channel material 224 may be epitaxially grown directly on a semiconductor layer of the support 222, in a process known as “monolithic integration.” In other such embodiments, the channel material 224 may be epitaxially grown on a semiconductor layer of another support structure and then the epitaxially grown layer of the channel material 224 may be transferred, in a process known as a “layer transfer,” to the support 222, in which case the support 222 may but does not have to include a semiconductor layer prior to the layer transfer. Layer transfer advantageously allows forming transistors over support structures or in layers that do not include semiconductor materials (e.g., in the back-end of an IC device). Layer transfer also advantageously allows forming transistors of any architecture (e.g., non-planar or planar transistors) without imposing the negative effects of the relatively high-temperature epitaxial growth process on devices that may already be present over a support structure.

The channel material 224 deposited at relatively low temperatures is typically a polycrystalline, polymorphous, or amorphous semiconductor, or any combination thereof. The channel material 224 epitaxially grown is typically a highly crystalline (e.g., monocrystalline, or single-crystalline) material. Therefore, whether the channel material 224 is deposited at relatively low temperatures or epitaxially grown can be identified by inspecting grain size of the active portions of the channel material 224 (e.g., of the portions of the channel material 224 that form channels of transistors). An average grain size of the channel material 224 being between about 0.5 and 1 millimeters (in which case the material may be polycrystalline) or smaller than about 0. 5millimeter (in which case the material may be polymorphous or amorphous) may be indicative of the channel material 224 having been deposited. On the other hand, an average grain size of the channel material 224 being equal to or greater than about 1 millimeter (in which case the material may be a single-crystal material) may be indicative of the channel material 224 having been epitaxially grown and included in the final device either by monolithic integration or by layer transfer.

The channel material 224 may have a thickness 223, which may be on the order of the target height of the pillars of the channel material 224 that will be formed in a subsequent process of the method 100. In some embodiments, the thickness 223 may be between about 20 and 5000 nanometers, including all values and ranges therein, e.g., between about 20 and 3000 nanometers or between about 20 and 2000 nanometers.

The method 100 may proceed with a process 104 that includes patterning the layer of a channel material provided in the process 102 to form one or more pillars of the channel material. An IC structure 204 of FIG. 2B illustrates an example result of the process 104. As shown in FIG. 2B, the IC structure 204 is similar to the IC structure 202 except that the channel material 224 is patterned in that some of the channel material 224 is removed to form three pillars 225 of the channel material 224, individually labeled as pillars 225-1, 225-2, and 225-3. In other embodiments, the IC structure 204 and subsequent IC structures illustrating the method 100 may include any other number of the pillars 225. The pillars 225 may extend away from the support 222 and be substantially perpendicular to the support 222 (e.g., having their longitudinal axes being substantially perpendicular to the support 222).

In various embodiments, any suitable patterning techniques may be used in the process 104 to form the pillars 225, such as, but not limited to, photolithographic or electron-beam (e-beam) patterning, possibly in conjunction with a suitable etching technique, e.g., a dry etch, such as e.g., radio frequency (RF) reactive ion etch (RIE) or inductively coupled plasma (ICP) RIE. In some embodiments, the etch performed in the process 104 may include an anisotropic etch, using etchants in a form of e.g., chemically active ionized gas (i.e., plasma) using e.g., bromine (Br) and chloride (Cl) based chemistries. In some embodiments, during the etch of the process 104, the IC structure may be heated to elevated temperatures, e.g., to temperatures between about room temperature and 200 degrees Celsius, including all values and ranges therein, to promote that byproducts of the etch are made sufficiently volatile to be removed from the surface.

As shown in the top-down view of FIG. 2B, in some embodiments, the pillars 225 may have a transversal cross-sectional shape (i.e., a shape in the x-y plane of the example coordinate system shown) that is substantially a circle. However, although the pillars 225 are illustrated in the present drawings as having circular cross-sections, the pillars 225 may instead have cross-sections that are rectangular, square, any other polygonal shape, any polygonal shape and rounded at corners, or irregularly shaped.

As shown in the cross-sectional side view of FIG. 2B, in some embodiments, in a cross- section of the pillars 225 along a plane perpendicular to the support 222, the pillars 225 may taper (e.g., the width of the pillars 225 may gradually decreases) away from the support 222. For example, an individual one of the pillars 225 may include a first end 221-1 and an opposite second end 221-2, wherein the first end 221-1 may be wider than the second end 221-2 and closer to the support 222 than the second end 221-2. In some embodiments, a width of an individual one of the pillars 225 (e.g., a dimension measured along the x-axis of the example coordinate system shown) at the second end 221-2 may be between about 1% and about 30% smaller than a width of the pillar 225 at the first end 221-1, including all values and ranges therein, e.g., between about 5% and about 25%, or between about 10% and about 20%. The pillars 225 tapering in a direction away from the support 222 may be indicative of the use of the method 100 because it is indicative of the fact that the pillars 225 are formed by a subtractive process where some of the channel material 224 is removed to form the pillars 225. In some embodiments, in a cross-section such as the one shown in FIG. 2B, a sidewall 232 of an individual one of the pillars 225 may have a portion that is at an angle less than about 8 degrees with respect to a line 234 perpendicular to the support 222, which may also be indicative of the use of the method 100.

In some embodiments, a height of an individual one of the pillars 225 (e.g., a dimension measured along the z-axis of the example coordinate system shown) may be substantially equal to, or slightly smaller (e.g., about 1-20% smaller) than, the thickness 223. In some embodiments, a height of an individual one of the pillars 225 may be at least about 3 times larger than an average width of an individual one of the pillars 225, including all values and ranges therein, e.g., at least about 4 times larger, or at least about 5 times larger. Phrased differently, an aspect ratio (e.g., a ratio of a height to a width) of an individual one of the pillars 225 may be at least about 3, at least about 4, or at least about 5, in various embodiments. In some embodiments, an average area of a transversal cross-section of an individual one of the pillars 225 (i.e., an area in the x-y plane of the example coordinate system shown) may be between about 25 and 10000 square nanometers, including all values and ranges therein (e.g., between about 25 and 1000 square nanometers, or between about 25 and 500 square nanometers).

The method 100 may further include proceed with a process 106 that includes depositing a gate insulator on sidewalls of the pillars formed in the process 104. An IC structure 206 of FIG. 2C illustrates an example result of the process 106. As shown in FIG. 2C, the IC structure 206 is similar to the IC structure 204 except that it further includes a gate insulator 226 on sidewalls 232 of the pillars 225. As shown in FIG. 2C, the gate insulator 226 may wrap entirely or almost entirely around sidewalls 232 of the pillars 225 (e.g., wrap around transversal portions of the pillars 225). In some embodiments, the gate insulator 226 may be deposited using any suitable deposition technique, e.g., using any suitable conformal deposition technique such as atomic layer deposition (ALD) or chemical vapor deposition (CVD).

In some embodiments, the gate insulator 226 may include one or more high-k dielectrics, e.g., insulator materials including elements such as hafnium, silicon, oxygen, titanium, tantalum, lanthanum, aluminum, zirconium, barium, strontium, yttrium, lead, scandium, niobium, and zinc. Examples of high-k materials that may be used for this purpose may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the gate insulator 226 during fabrication of the IC structures to improve the quality of the gate insulator 226. The gate insulator 226 may have a thickness that may, in some embodiments, be between about 0.5 nanometers and 10 nanometers, including all values and ranges therein (e.g., between about 0.5 and 3 nanometers, between about 1 and 3 nanometers, or between about 1 and 2 nanometers).

In some embodiments, e.g., when a transistor formed with its channel region being in a portion of one or more of the pillars 225 is a storage transistor of a hysteretic memory cell (i.e., a type of memory that functions based on the phenomenon of hysteresis), the gate insulator 226 may be replaced with, or complemented by, a hysteretic material or a hysteretic arrangement, which, together, may be referred to as a “hysteretic element.” Transistors in which the gate insulator 226 includes a hysteretic element may be described as “hysteretic transistors” and may be used to implement hysteretic memory. Hysteretic memory refers to a memory technology employing hysteretic materials or arrangements, where a material or an arrangement may be described as hysteretic if it exhibits the dependence of its state on the history of the material (e.g., on a previous state of the material). Ferroelectric (FE) and antiferroelectric (AFE) materials are one example of hysteretic materials. Layers of different materials arranged in a stack to exhibit charge-trapping phenomena is one example of a hysteretic arrangement.

A FE or an AFE material is a material that exhibits, over some range of temperatures, spontaneous electric polarization, i.e., displacement of positive and negative charges from their original position, where the polarization can be reversed or reoriented by application of an electric field. In particular, an AFE material is a material that can assume a state in which electric dipoles from the ions and electrons in the material may form a substantially ordered (e.g., substantially crystalline) array, with adjacent dipoles being oriented in opposite (antiparallel) directions (i.e., the dipoles of each orientation may form interpenetrating sub-lattices, loosely analogous to a checkerboard pattern), while a FE material is a material that can assume a state in which all of the dipoles point in the same direction. Because the displacement of the charges in FE and AFE materials can be maintained for some time even in the absence of an electric field, such materials may be used to implement memory cells. Because the current state of the electric dipoles in FE and AFE materials depends on the previous state, such materials are hysteretic materials. Memory technology where logic states are stored in terms of the orientation of electric dipoles in (i.e., in terms of polarization of) FE or AFE materials is referred to as “FE memory,” where the term “ferroelectric” is said to be adopted to convey the similarity of FE memories to ferromagnetic memories, despite the fact that there is typically no iron (Fe) present in FE or AFE materials.

A stack of alternating layers of materials that is configured to exhibit charge-trapping is an example of a hysteretic arrangement. Such a stack may include as little as two layers of materials, one of which is a charge-trapping layer (i.e., a layer of a material configured to trap charges when a volage is applied across the material) and the other one of which is a tunnelling layer (i.e., a layer of a material through which the charge is to be tunneled to the charge-trapping layer). The tunnelling layer may include an insulator material such as a material that includes silicon and oxygen (e.g., silicon oxide), or any other suitable insulator. The charge-trapping layer may include a metal or a semiconductor material that is configured to trap charges. For example, a material that includes silicon and nitrogen (e.g., silicon nitride) may be used in/as a charge-trapping layer. Because the trapped charges may be kept in a charge-trapping arrangement for some time even in the absence of an electric field, such arrangements may be used to implement memory cells. Because the presence and/or the amount of trapped charges in a charge-trapping arrangement depends on the previous state, such arrangements are hysteretic arrangements. Memory technology where logic states are stored in terms of the amount of charge trapped in a hysteretic arrangement may be referred to as “charge-trapping memory.”

Hysteretic memories have the potential for adequate non-volatility, short programming time, low power consumption, high endurance, and high-speed writing. In addition, hysteretic memories may be manufactured using processes compatible with the standard CMOS technology. Therefore, over the last few years, these types of memories have emerged as promising candidates for many growing applications.

In some embodiments, the hysteretic element of the gate insulator 226 may be provided as a layer of a FE or an AFE material. Such an FE/AFE material may include one or more materials that can exhibit sufficient FE/AFE behavior even at thin dimensions, such as an insulator material at least about 5%, e.g., at least about 7% or about 10%, of which is in an orthorhombic phase and/or a tetragonal phase (e.g., as a material in which at most about 95-90% of the material may be amorphous or in a monoclinic phase). For example, such materials may be based on hafnium and oxygen (e.g., hafnium oxides), with various dopants added to ensure sufficient amount of an orthorhombic phase or a tetragonal phase. Some examples of such materials include materials that include hafnium, oxygen, and zirconium (e.g., hafnium zirconium oxide (HfZrO, also referred to as HZO)), materials that include hafnium, oxygen, and silicon (e.g., silicon-doped (Si-doped) hafnium oxide), materials that include hafnium, oxygen, and germanium (e.g., germanium-doped (Ge-doped) hafnium oxide), materials that include hafnium, oxygen, and aluminum (e.g., aluminum-doped (Al-doped) hafnium oxide), and materials that include hafnium, oxygen, and yttrium (e.g., yttrium-doped (Y-doped) hafnium oxide). However, in other embodiments, any other materials which exhibit FE/AFE behavior at thin dimensions may be used as the hysteretic element and are within the scope of the present disclosure.

In other embodiments, the hysteretic element of the gate insulator 226 may be provided as a stack of alternating layers of materials that can trap charges. In some embodiments, the process 106 may include sequentially depositing the alternating layers of materials of the charge-trapping arrangement of the gate insulator 226 onto the sidewalls 232 of the pillars 225. In some such embodiments, the stack may be a two-layer stack, where one layer is a charge-trapping layer and the other layer is a tunnelling layer. The tunnelling layer may include an insulator material such as a material that includes silicon and oxygen (e.g., silicon oxide), or any other suitable insulator. The charge-trapping layer may include an electrically conductive material such as a metal, or a semiconductor material. In some embodiments, the charge-trapping layer may include a material that includes silicon and nitrogen (e.g., silicon nitride). In general, any material that has defects that can trap charge may be used in/as a charge-trapping layer. Such defects are very detrimental to operation of logic devices and, therefore, typically, deliberate steps need to be taken to avoid presence of the defects. However, for memory devices, such defects are desirable because charge- trapping may be used to represent different memory states of a memory cell.

In some embodiments of the hysteretic element being provided as a stack of alternating layers of materials that can trap charges, the stack may be a three-layer stack where an insulator material is provided on both sides of a charge-trapping layer. In such embodiments, a layer of an insulator material on one side of the charge-trapping layer may be referred to as a “tunnelling layer” while a layer of an insulator material on the other side of the charge-trapping layer may be referred to as a “field layer.”

In various embodiments of the hysteretic element being provided as a stack of alternating layers of materials that can trap charges, a thickness of each layer the stack (e.g., a dimension measured in a direction perpendicular to the sidewalls 232 of the pillars 225) may be between about 0.5 and 10 nanometers, including all values and ranges therein, e.g., between about 0.5 and 5 nanometers. In some embodiment of a three-layer stack, a thickness of each layer of the insulator material may be about 0.5 nanometers, while a thickness of the charge-trapping layer may be between about 1 and 8 nanometers, e.g., between about 2.5 and 7.5 nanometers, e.g., about 5 nanometers. In some embodiments, a total thickness of the hysteretic element provided as a stack of alternating layers of materials that can trap charges (i.e., a hysteretic arrangement) may be between about 1 and 10 nanometers, e.g., between about 2 and 8 nanometers, e.g., about 6 nanometers.

The method 100 may then proceed with a process 108 that includes depositing an insulator material around the pillars with the gate insulator provided in the process 106. An IC structure 208 of FIG. 2D illustrates an example result of the process 108. As shown in FIG. 2D, the IC structure 208 is similar to the IC structure 206 except that it further includes an insulator material 228 between and above the pillars 225. The insulator material 228 may include any suitable insulator, e.g., any suitable insulator used as interlayer dielectric (ILD) in IC structures. In some embodiments, the insulator material 228 may include a low-k dielectric material. Some examples of low-k dielectric materials include, but are not limited to, silicon dioxide, carbon-doped oxide, silicon nitride, organic polymers such as perfluorocyclobutane or polytetrafluoroethylene, fused silica glass (FSG), and organosilicates such as silsesquioxane, siloxane, or organosilicate glass. In some embodiments, the insulator material 228 may include pores or air gaps to further reduce its dielectric constant. Examples of deposition techniques that may be used to provide the insulator material 228 in the process 108 include, but are not limited to, spin-coating, dip-coating, ALD, CVD, or physical vapor deposition (PVD) (e.g., evaporative deposition, magnetron sputtering, or e-beam deposition).

As shown in the cross-sectional side view of FIG. 2D, in some embodiments, deposition of the insulator material 228 may result in overburden or excess 227 of the insulator material 228 above the pillars 225. In such embodiments, the method 100 may include a process 110 in which the insulator material deposited in the process 108 is planarized so that it does not extend past the pillars 225. An IC structure 210 of FIG. 2E illustrates an example result of the process 110. As shown in FIG. 2E, the IC structure 210 is similar to the IC structure 208 except that the overburden or excess 227 of the insulator material 228 above the pillars 225 that was present in the IC structure 208 is removed, so that the top of the insulator material 228 is substantially aligned with the top of the pillars 225. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface of the insulator material 228.

Next, the method 100 may proceed with a process 112 that includes etching the insulator material 228 down so that it has a target thickness above the support 222. An IC structure 212 of FIG. 2F illustrates an example result of the process 112. As shown in FIG. 2F, the IC structure 212 is similar to the IC structure 210 except that the insulator material 228 is lowered so that it has a thickness 229 (e.g., a dimension measured along the z-axis of the example coordinate system shown). Looking ahead at the method 100, FIG. 1 illustrates that, in a subsequent process 114, a gate electrode material will be deposited over the insulator material 228 and, in a process 116, the gate electrode material will be etched to achieve a target thickness, and then a sequence of the processes 108, 110, 112, 114, and 116 may be repeated to reach a desired number of alternating layers of the insulator material 228 and the gate electrode material. The layers of gate electrode materials may act as gates of transistors having channel regions in portions of the channel material 224 of the pillars 225. The height of the pillars 225 and the desired number of gates vertically stacked along the pillars 225 may then define what the thicknesses of the insulator material 228 and the gate electrode material should be. For example, in some embodiments, the thickness 229 of the insulator material 228 may be about 5-50%, e.g., about 5%-30% or about 5%-20% of the height of the pillars 225. Any suitable etching technique, e.g., a dry etch, such as RIE or ICP RIE, may be used to etch the insulator material 228 to the thickness 229 in the process 112. In some embodiments, planarization of the process 110 may be a part of the process 112 and the process 110 may be omitted from the method 100. In other embodiments, the insulator material 228 may be deposited in the process 108 so that, in areas between the pillars 225, it does not extend beyond the top surface of the pillars 225, in which case the process 110 may be omitted from the method 100 as well.

The method 100 may then proceed with a process 114 that includes depositing a gate electrode material around the pillars 225, above the insulator material 228 etched to the target thickness in the process 112. An IC structure 214 of FIG. 2G illustrates an example result of the process 114. As shown in FIG. 2G, the IC structure 214 is similar to the IC structure 212 except that it further includes a gate electrode material 230 around the pillars 225, above the insulator material 228. The gate electrode material 230 may include at least one P-type work function metal or N-type work function metal, depending on whether a transistor of which it will be a part of is to be a PMOS transistor or an NMOS transistor. For example, a P-type work function metal may be used as the gate electrode material 230 when a transistor is a PMOS transistor, and an N-type work function metal may be used as the gate electrode material 230 when a transistor is an NMOS transistor. For a PMOS transistor, metals that may be used for the gate electrode material 230 may include, but are not limited to, ruthenium, palladium, platinum, cobalt, nickel, and conductive metal oxides (e.g., ruthenium oxide). For an NMOS transistor, metals that may be used for the gate electrode material 230 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode material 230 may include a stack of two or more metal layers, where one or more metal layers are work function metal layers and at least one metal layer is a fill metal layer. Further metal layers may be included for other purposes, such as a barrier layer (e.g., tantalum, tantalum nitride, an aluminum-containing alloy, etc.). In some embodiments, the gate electrode material 230 may include a resistance-reducing cap layer (e.g., copper, gold, cobalt, or tungsten). Further layers may be included next to the gate electrode material 230 for other purposes, such as to act as a diffusion barrier layer or/and an adhesion layer. Examples of deposition techniques that may be used to provide the gate electrode material 230 in the process 114 include, but are not limited to, ALD, CVD, PVD (e.g., sputtering or evaporation), plasma-enhanced CVD (PECVD), or chemical solution deposition.

Next, the method 100 may proceed with a process 116 that includes etching the gate electrode material 230 down so that it has a target thickness above the support 222. An IC structure 216 of FIG. 2H illustrates an example result of the process 116. As shown in FIG. 2H, the IC structure 216 is similar to the IC structure 214 except that the gate electrode material 230 is lowered so that it has a thickness 231 (e.g., a dimension measured along the z-axis of the example coordinate system shown). The layer of gate electrode material 230 of the IC structure 216 may form gates of transistors having channel regions in portions of the channel material 224 of the pillars 225 that are wrapped around by the gate electrode material 230 of the IC structure 216. Thus, similar to the thickness 229 of the insulator material 228, the height of the pillars 225 and the desired number of gates vertically stacked along the pillars 225 may then define what the thickness 231 of the gate electrode material 230 should be. For example, in some embodiments, the thickness 231 of the gate electrode material 230 may be about 5-50%, e.g., about 5%-30% or about 5%-20% of the height of the pillars 225. Any suitable etching technique, e.g., a dry etch, such as RIE or ICP RIE, may be used to etch the gate electrode material 230 to the thickness 231 in the process 116. In some embodiments, if the gate electrode material 230 is originally deposited with an overburden or excess extending above the pillars 225 (e.g., as is shown in FIG. 2G), the process 116 may include any suitable process to planarize the gate electrode material 230 so that the upper surface of the gate electrode material 230 is aligned with the upper surface of the pillars 225, and then etching the gate electrode material 230 to further lower its upper surface until the gate electrode material 230 has the thickness 231. In other embodiments, the gate electrode material 230 may be deposited in the process 114 so that, in areas between the pillars 225, it does not extend beyond the top surface of the pillars 225, in which case planarization may be omitted from the process 116.

The method 100 may further include a process 118 that includes repeating processes 108-116 to reach a target number of alternating layers of the insulator material 228 and the gate electrode material 230. An IC structure 218 of FIG. 21 illustrates an example result of the process 118. As shown in FIG. 21, the IC structure 218 is similar to the IC structure 216 except that it includes additional pairs of the insulator material 228 and the gate electrode material 230.

If it is desired that the layer closest to the top surfaces of the pillars 225 is an insulator layer, the method 100 may further include a process 120 that includes depositing and, optionally, planarizing another layer of the insulator material 228. An IC structure 220 of FIG. 2J illustrates an example result of the process 120. As shown in FIG. 2J, the IC structure 220 is similar to the IC structure 218 except that it includes an additional layer of the insulator material 228 as the layer closest to the top surfaces of the pillars 225. In other embodiments, the process 120 may be omitted, in which case the upper-most layer of the gate electrode material 230 may either be below the top surfaces of the pillars 225 (e.g., as shown in FIG. 21), extend above the top surfaces of the pillars 225 (e.g., as shown in FIG. 2G), or be substantially aligned with the top surfaces of the pillars 225 (e.g., similar to how it is shown in FIG. 2J for the insulator material 228). In any case, the alternating layers of the insulator material 228 and the gate electrode material 230 around the pillars 225 may extend substantially parallel to the support 222 and substantially perpendicular to the longitudinal axes of the pillars 225, as shown in FIG. 2J. The process 120 may be performed similar to the process 108 and process 110, described above.

As shown in FIG. 2J, the IC structure 220 includes elongated vertical structures of the channel material 224 in the form of the pillars 225, where the gate insulator 226 is provided on one or more sidewalls 232 of the pillars 225. The IC structure 220 further includes lines or planes of the gate electrode material 230 (or, more generally, of a conductive material) alternating with lines or planes of the insulator material 228 extending substantially parallel to the support 222 and at least partially wrapping around different sections of the elongated vertical structures of the channel material 224 of the pillars 225. As also shown in FIG. 2J, the IC structure 220 may include a gate insulator 226 on one or more sidewalls 232 of the pillars 225 and further include the gate electrode material 230 (or, more generally, of a conductive material) wrapping around portions of the gate insulator 226. Sections of the channel material 224 of the pillars 225 around which the gate electrode material 230 wraps around may then form channel regions of transistors provided along the pillars 225.

FIGS. 3A-3E provide cross-sectional side views of the pillars 225 with different sidewall profiles that may be realized using the method 100 of FIG. 1, according to some embodiments. Each of FIGS. 3A-3E provides a cross-sectional illustration similar to the illustrations of the cross-sections in the x-z planes of FIGS. 2A-2J, but omitting other portions of the IC structures besides the pillars 225 in order to not clutter the drawings. FIG. 3A illustrates a pillar 325 that is an example of any of the pillars 225 of FIG. 2B and is substantially the same in shape as the pillars 225 shown in FIG. 2B, as described above. FIGS. 3B-3E provide alternative shapes of the pillars 325, where each of the pillars 325 shown in FIG. 3B-3E may be used as any of the pillars 225 of the IC structure 204 of FIG. 2B and the subsequent drawings of FIGS. 2C-2J, and, in some embodiments, the IC structure 204 and the subsequent IC structures of FIGS. 2C-2J may include any combination of pillars 325 shown in FIGS. 3A-3E.

Each of FIG. 3B-3E illustrates a pillar 325 that may have first sections 302 alternating with second sections 304. The first sections 302 are vertical portions of the pillar 325 that, from the top to the bottom of the pillar 325, widen at a lower rate than the second sections 304. Thus, the second sections 304 are vertical portions of the pillar 325 that, from the top to the bottom of the pillar 325, widen at a higher rate than the first sections 302. Phrased differently, in the cross-section of the pillar along the plane perpendicular to the support 222, as shown in FIGS. 3B-3E, a change in width of the pillar 325 per unit height of the pillar 325 is greater for the first sections 302 than for the second sections 304. The first sections 302 and the second sections 304 may be different because different etching techniques were used to form them. For example, atomic layer etching (ALE) is an etching technique that removes a material (e.g., the channel material 224) one or a few atomic layers at a time. ALE is a technique that allows precise control over material removal at the atomic level and may be used for etching layers of the channel material 224 (e.g., in the process 104) with high precision and uniformity. If ALE is employed to form a portion of a pillar 225 in the process 104, that portion of the pillar 225 may widen less than if a non-ALE etching technique is used. However, ALE may be a relatively slow process, and, therefore, it may be advantageous to mix it up with a faster non-ALE techniques. Non-ALE techniques may remove the channel material 224 more quickly than ALE, but sacrifice some level of precision compared to ALE, thus widening the pillar 325 more, from the top to the bottom. Examples of non-ALE techniques include RIE, deep RIE (DRIE), wet chemical etching, plasma etching, and laser ablation. FIGS. 3B-3E illustrate sections 302 alternating with sections 304 multiple times, e.g., shown as, from the top to the bottom of the pillar 325, as a sequence of a first section 302-1, a second section 304-1, a first section 302-2, a second section 304-2, a first section 302-3, and a second section 304-3. In other embodiments, other number of the first sections 302 and the second sections 304 may be provided along a pillar 325, and/or different instances of the first sections 302 and the second sections 304 may be arranged differently with respect to one another. For FIGS. 3B, 3C, and 3E, the heights of the second sections 304 are greater than the heights of the first sections 302, which may be advantageous in terms of, e.g., faster formation of the pillar 325. For FIG. 3D, the heights of the first sections 302 are greater than the heights of the second sections 304, which may be advantageous in terms of, e.g., a greater uniformity of the width of the pillar 325 for the larger vertical portions of the pillar 325. FIG. 3E further illustrates that, in some embodiments, in the cross-section of the pillar 325 along the plane perpendicular to the support 222, at least a portion of a sidewall 232 of the pillar 325 may have an undulating profile, which may be characteristic of a use of a combination of anisotropic and isotropic etching processes and may be advantageous because it may be faster and/or simpler and/or less expensive than other etching techniques.

Turning to the second method, as shown in FIG. 4, the method 400 may begin with a process 402 that includes providing one or more structures of a seed material over a support. An IC structure 502 of FIG. 5A illustrates an example result of the process 402. As shown in FIG. 5A, the IC structure 502 illustrates a support 522 and three structures of a seed material 534 over the support 522. FIG. 5A illustrates that the IC structure 502 may further include a layer of a semiconductor material 524 over the support 522, and the structures of the seed material 534 may be provided in the upper portion of the layer of the semiconductor material 524. Descriptions provided for the support 222 are applicable to the support 522 and, in the interest of brevity, are not repeated. The seed material 534 may include any suitable material that may act as a seed for epitaxially growing a semiconductor material from it in a later process (e.g., in a process 410 of the method 400). Because the seed material 534 will later serve as a template for epitaxially growing a semiconductor material with a specific crystal orientation, the choice of the seed material 534 will influence the crystal structure and quality of the epitaxially grown semiconductor material of the process 410. In some embodiments, the upper layer of the support 522 may be an insulator and the seed material 534 may be inserted as islands into the upper layer of the support 522. In some embodiments, the semiconductor material 524 may be provided over the support 522, and the seed material 534 may be inserted as islands into the upper layer of the semiconductor material 524. As shown in FIG. 5A, in some such embodiments, crystal orientation and/or grain orientation of the semiconductor material 524 may be different from crystal orientation and/or grain orientation of the seed material 534. In FIGS. 5A-5E, crystal orientation and/or grain orientation of different materials are shown as slanted lines representing grains having a certain example preferential orientation. Materials shown in FIGS. 5A-5E with slanted lines extending in different directions (e.g., the semiconductor material 524 and the seed material 534) represent material having different crystal orientation and/or grain orientation.

The method 400 may then proceed with a process 404 that includes depositing a stack of alternating layers of an insulator material and a gate electrode material. An IC structure 504 of FIG. 5B illustrates an example result of the process 404. As shown in FIG. 5B, the IC structure 504 is similar to the IC structure 502 except that it further includes a stack of alternating layers of an insulator material 528 and a gate electrode material 530. Descriptions provided for the insulator material 228, the gate electrode material 230, and their respective thicknesses 229 and 231 are applicable to the insulator material 528, the gate electrode material 530, and their respective thicknesses and, in the interest of brevity, are not repeated.

The method 400 may further include a process 406 that includes forming openings in the stack of alternating layers deposited in the process 404, exposing the seed material 534 at the bottom of the openings. An IC structure 506 of FIG. 5C illustrates an example result of the process 406. As shown in FIG. 5C, openings 535-1, 535-2, and 535-3 (together referred to as “openings 535”) may extend from the top of the stack of the alternating layers of the insulator material 528 and the gate electrode material 530, reaching the seed material 534 at the bottom. Any suitable etching technique, such as any suitable anisotropic etching technique, may be used to form the openings 535. Indicative of the use of the method 400, the openings 535 may have a tapered shape as shown in the cross-sectional side view of FIG. 5C, where the openings 535 narrow towards the bottom. In some embodiments, dimensions and/or shapes of the openings 535 may be substantially as described above with respect to the dimensions and/or shapes of the pillars 225.

Next, the method 400 may include a process 408 that includes depositing a gate insulator on sidewalls of the openings formed in the process 406. An IC structure 508 of FIG. 5D illustrates an example result of the process 408. As shown in FIG. 5D, a gate insulator 526 may be deposited on the sidewalls of the openings 535, leaving at least portions of the seed material 534 at the bottom of the openings 535 exposed so that epitaxial growth may initiate from the seed material 534 in the next process of the method 400. Descriptions provided for the gate insulator 226 are applicable to the gate insulator 526 and, in the interest of brevity, are not repeated.

The method 400 may further include a process 410 in which a channel material is epitaxially grown in the openings lined with the gate insulator formed in the process 408. An IC structure 510 of FIG. 5E illustrates an example result of the process 410. As shown in FIG. 5E, a channel material 544 may at least partially, or fully, fill the openings 535. The channel material 544 may include any of the materials described with reference to the channel material 224 that may be epitaxially grown materials. Because the channel material 544 is epitaxially grown, it may be a highly crystalline (e.g., monocrystalline, or single-crystalline) material and may have an average grain size being equal to or greater than about 1 millimeter. Furthermore, because the channel material 544 is grown from the seed material 534 at the bottom of the openings 535, the channel material 544 may substantially adopt the crystal lattice orientation and/or the grain orientation of the seed material 534, which may be distinctly different from the crystal lattice orientation and/or the grain orientation of the semiconductor material 524 and/or of the support 522. The epitaxial growth of the process 410 may adapt the crystal/grain orientation of the seed material 534 by facilitating the controlled deposition of atoms or molecules from precursor gases onto the seed material's surface, leading to the growth of layers of the channel material 544 with a matching crystal lattice and/or grain structure. Imperfections may arise during the epitaxial growth of the channel material 544, so, as used herein, crystal lattice/grain orientations of two materials being matching refers to crystal lattice/grain orientations matching for at least 80% of the two materials. This may be the case for the channel material 544 and the seed material 534.

As shown in FIG. 5E, the IC structure 510 includes elongated vertical structures of the channel material 544, where the gate insulator 526 is provided on one or more sidewalls of the elongated vertical structures of the channel material 544. The IC structure 510 further includes lines or planes of the gate electrode material 530 (or, more generally, of a conductive material) alternating with lines or planes of the insulator material 528 extending substantially parallel to the support 522 and at least partially wrapping around different sections of the elongated vertical structures of the channel material 544. As also shown in FIG. 5E, the IC structure 510 may include a gate insulator 526 on one or more sidewalls of the elongated vertical structures of the channel material 544 and further include the gate electrode material 530 (or, more generally, of a conductive material) wrapping around portions of the gate insulator 526. Sections of the channel material 544 of the elongated vertical structures of the channel material 544 around which the gate electrode material 530 wraps around may then form channel regions of transistors provided along the elongated vertical structures of the channel material 544.

FIGS. 6A-6B provide cross-sectional side and top-down views of alternative implementations of the IC structures 510 that may be realized using the method 400 of FIG. 4, according to some embodiments. Each of FIGS. 6A-6B provides cross-sectional side and top-down views similar to those shown in FIG. 5E. FIG. 6A illustrates that, in some embodiments of the IC structure 510, the seed material 534 may be provided as a materially continuous layer forming bottoms of different openings 535 in which the channel material 544 is epitaxially grown. FIG. 6B illustrates that the seed material 534 may be omitted and, instead, the semiconductor material 524 which may be part (upper layer) of the support 522 may be used as the seed material from which the epitaxial growth of the channel material 544 may start in the openings 535. In such embodiments, as shown in FIG. 6B, the crystal lattice orientation and/or the grain orientation of the channel material 544 may be substantially the same (e.g., at least 80% same) as the crystal lattice orientation and/or the grain orientation of the semiconductor material 524.

Various arrangements of the IC structures as illustrated in FIGS. 1-6 do not represent an exhaustive set of IC devices that may implement IC structures with elongated vertical structures of channel materials as described herein, but merely provide examples of such devices/structures/assemblies. For example, while the pillars 225 and the openings 535 are shown in the present drawings to have circular transverse cross-sections, in other embodiments, they may have any other transverse cross-sectional shapes, of which being within the scope of the present disclosure. In another example, an IC structure may include a combination of one or more elongated vertical structures of the channel material 224 in the form of the pillars 225 as well as one or more elongated vertical structures of the channel material 544 within the openings 535, as described herein. The number and positions of various elements shown in FIGS. 1-6 is purely illustrative and, in various other embodiments, other numbers of these elements, provided in other locations relative to one another may be used in accordance with the general architecture considerations described herein.

Arrangements with one or more IC structures with elongated vertical structures of channel materials as disclosed herein may be included in any suitable electronic device. FIGS. 7-11 illustrate various examples of devices and components that may include one or more IC structures with elongated vertical structures of channel materials as disclosed herein, e.g., any of the IC structures 220 or 510, or any combination of such IC structures.

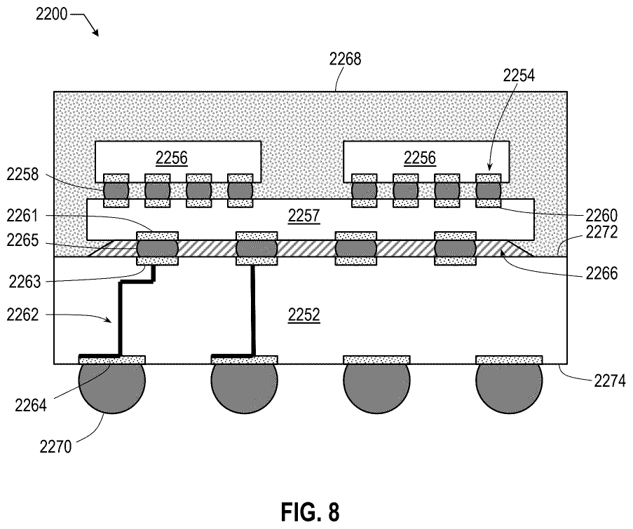

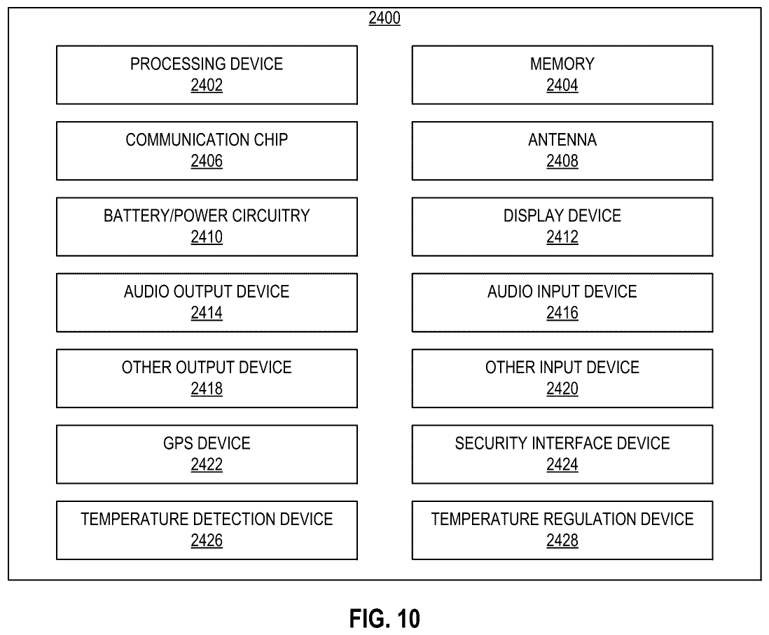

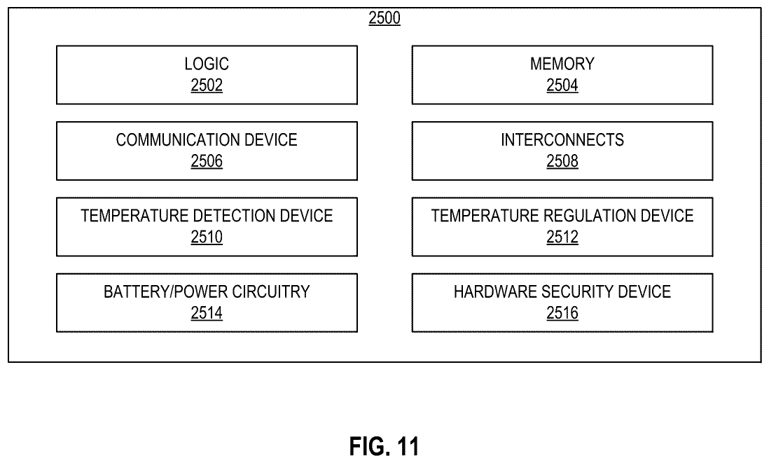

FIG. 7 illustrates top views of a wafer 2000 and dies 2002 that may include one or more IC structures with elongated vertical structures of channel materials in accordance with any of the embodiments disclosed herein. In some embodiments, the dies 2002 may be included in an IC package, in accordance with any of the embodiments disclosed herein. For example, any of the dies 2002 may serve as any of the dies 2256 in an IC package 2200 shown in FIG. 8. The wafer 2000 may be composed of semiconductor material and may include one or more dies 2002 having IC structures formed on a surface of the wafer 2000. Each of the dies 2002 may be a repeating unit of a semiconductor product that includes any suitable IC (e.g., ICs including one or more IC structures with elongated vertical structures of channel materials as described herein). After the fabrication of the semiconductor product is complete (e.g., after manufacture of any embodiment of the IC structures 220 or 510, or any combination of such IC structures), the wafer 2000 may undergo a singulation process in which each of the dies 2002 is separated from one another to provide discrete “chips” of the semiconductor product. In particular, devices that include one or more IC structures with elongated vertical structures of channel materials as disclosed herein may take the form of the wafer 2000 (e.g., not singulated) or the form of the die 2002 (e.g., singulated). The die 2002 may include supporting circuitry to route electrical signals to various memory cells, transistors, capacitors, as well as any other IC components. In some embodiments, the wafer 2000 or the die 2002 may implement or include a memory device (e.g., a floating body memory device with programmable gates as described herein), a logic device (e.g., an AND, OR, NAND, or NOR gate), or any other suitable circuit element. Multiple ones of these devices may be combined on a single die 2002. For example, a memory array formed by multiple memory devices may be formed on a same die 2002 as a processing device (e.g., the processing device 2402 of FIG. 10 or the logic circuitry 2502 of FIG. 11) or other logic that is configured to store information in the memory devices or execute instructions stored in the memory array.

FIG. 8 is a side, cross-sectional view of an example IC package 2200 that may include one or more IC structures with elongated vertical structures of channel materials in accordance with any of the embodiments disclosed herein. In some embodiments, the IC package 2200 may be a system-in-package (SiP).

The package substrate 2252 may be formed of a dielectric material (e.g., a ceramic, a buildup film, an epoxy film having filler particles therein, etc.), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 8 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 8 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

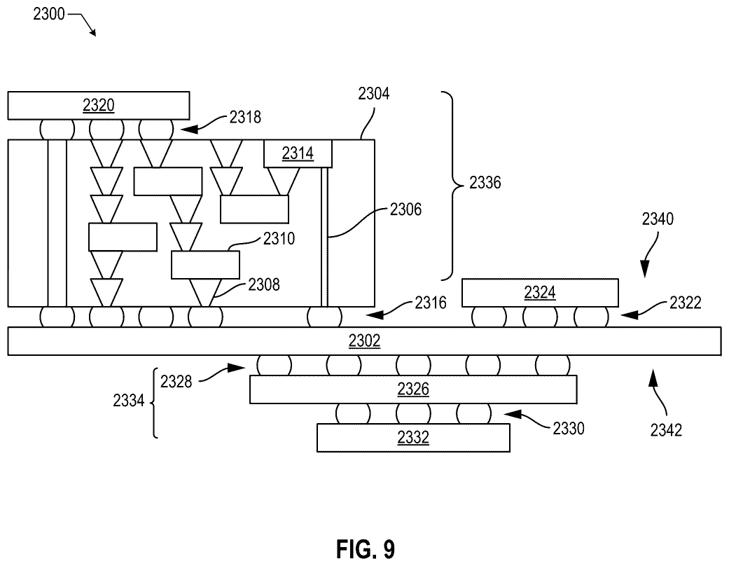

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 8 are solder balls (e.g., for a ball grid array arrangement), but any suitable second-level interconnects 2270 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 9.

The dies 2256 may take the form of any of the embodiments of the die 2002 discussed herein (e.g., may include any of the embodiments of the IC structures with elongated vertical structures of channel materials as described herein). In embodiments in which the IC package 2200 includes multiple dies 2256, the IC package 2200 may be referred to as a multi-chip package (MCP). The dies 2256 may include circuitry to perform any desired functionality. For example, one or more of the dies 2256 may be logic dies (e.g., silicon-based dies), and one or more of the dies 2256 may be memory dies (e.g., high bandwidth memory), including embedded memory dies as described herein. In some embodiments, any of the dies 2256 may include one or more IC structures with elongated vertical structures of channel materials, e.g., as discussed above; in some embodiments, at least some of the dies 2256 may not include any IC structures with elongated vertical structures of channel materials.

The IC package 2200 illustrated in FIG. 8 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 8, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 9 is a cross-sectional side view of an IC device assembly 2300 that may include components having one or more IC structures with elongated vertical structures of channel materials in accordance with any of the embodiments disclosed herein. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of one or more IC structures with elongated vertical structures of channel materials in accordance with any of the embodiments disclosed herein; e.g., any of the IC packages discussed below with reference to the IC device assembly 2300 may take the form of any of the embodiments of the IC package 2200 discussed above with reference to FIG. 8 (e.g., may include one or more IC structures with elongated vertical structures of channel materials provided on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 9 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 9), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 7), an IC device, or any other suitable component. In particular, the IC package 2320 may include one or more IC structures with elongated vertical structures of channel materials as described herein. Although a single IC package 2320 is shown in FIG. 9, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 9, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group III-V and group IV materials. The interposer 2304 may include metal interconnects 2308 and vias 2310, including but not limited to through-silicon vias (TSVs) 2306. The interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) protection devices, and memory devices. More complex devices such as RF devices, power amplifiers, power management devices, antennas, arrays, sensors, and microelectromechanical systems (MEMS) devices may also be formed on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 9 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

FIG. 10 is a block diagram of an example computing device 2400 that may include one or more components including IC structures with elongated vertical structures of channel materials in accordance with any of the embodiments disclosed herein. For example, any suitable ones of the components of the computing device 2400 may include a die (e.g., the die 2002 of FIG. 7) having one or more IC structures with elongated vertical structures of channel materials as described herein. Any one or more of the components of the computing device 2400 may include, or be included in, an IC package 2200 of FIG. 8 or an IC device assembly 2300 of FIG. 9.

A number of components are illustrated in FIG. 10 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single system-on-chip (SoC) die.

Additionally, in various embodiments, the computing device 2400 may not include one or more of the components illustrated in FIG. 10, but the computing device 2400 may include interface circuitry for coupling to the one or more components. For example, the computing device 2400 may not include a display device 2412, but may include display device interface circuitry (e.g., a connector and driver circuitry) to which a display device 2412 may be coupled. In another set of examples, the computing device 2400 may not include an audio input device 2416 or an audio output device 2414, but may include audio input or output device interface circuitry (e.g., connectors and supporting circuitry) to which an audio input device 2416 or audio output device 2414 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), non-volatile memory (e.g., read-only memory (ROM)), flash memory, solid state memory, and/or a hard drive. In some embodiments, the memory 2404 may include memory that shares a die with the processing device 2402. This memory may be used as cache memory and may include embedded DRAM (eDRAM) or spin transfer torque MRAM. In some embodiments, the memory 2404 may include one or more IC structures with elongated vertical structures of channel materials as described herein.

In some embodiments, the computing device 2400 may include a communication chip 2406 (e.g., one or more communication chips). For example, the communication chip 2406 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2406 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 2406 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2406 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2406 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2406 may operate in accordance with other wireless protocols in other embodiments. The computing device 2400 may include an antenna 2408 to facilitate wireless communications and/or to receive other wireless communications (such as AM or FM radio transmissions).

In some embodiments, the communication chip 2406 may manage wired communications, such as electrical, optical, or any other suitable communication protocols (e.g., the Ethernet). As noted above, the communication chip 2406 may include multiple communication chips. For instance, a first communication chip 2406 may be dedicated to shorter-range wireless communications such as Wi-Fi or Bluetooth, and a second communication chip 2406 may be dedicated to longer-range wireless communications such as global positioning system (GPS), EDGE, GPRS, CDMA, WiMAX, LTE, EV-DO, or others. In some embodiments, a first communication chip 2406 may be dedicated to wireless communications, and a second communication chip 2406 may be dedicated to wired communications.

The computing device 2400 may include a battery/power circuitry 2410. The battery/power circuitry 2410 may include one or more energy storage devices (e.g., batteries or capacitors) and/or circuitry for coupling components of the computing device 2400 to an energy source separate from the computing device 2400 (e.g., AC line power).

The computing device 2400 may include a display device 2412 (or corresponding interface circuitry, as discussed above). The display device 2412 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2414 (or corresponding interface circuitry, as discussed above). The audio output device 2414 may include any device that generates an audible indicator, such as speakers, headsets, or earbuds, for example.

The computing device 2400 may include an audio input device 2416 (or corresponding interface circuitry, as discussed above). The audio input device 2416 may include any device that generates a signal representative of a sound, such as microphones, microphone arrays, or digital instruments (e.g., instruments having a musical instrument digital interface (MIDI) output).

The computing device 2400 may include an other output device 2418 (or corresponding interface circuitry, as discussed above). Examples of the other output device 2418 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may include a GPS device 2422 (or corresponding interface circuitry, as discussed above). The GPS device 2422 may be in communication with a satellite-based system and may receive a location of the computing device 2400, as known in the art.

The computing device 2400 may include a security interface device 2424. The security interface device 2424 may include any device that provides security features for the computing device 2400 or for any individual components therein (e.g., for the processing device 2402 or for the memory 2404). Examples of security features may include authorization, access to digital certificates, access to items in keychains, etc. Examples of the security interface device 2424 may include a software firewall, a hardware firewall, an antivirus, a content filtering device, or an intrusion detection device.

In some embodiments, the computing device 2400 may include a temperature detection device 2426 and a temperature regulation device 2428.

The temperature detection device 2426 may include any device capable of determining temperatures of the computing device 2400 or of any individual components therein (e.g., temperatures of the processing device 2402 or of the memory 2404). In various embodiments, the temperature detection device 2426 may be configured to determine temperatures of an object (e.g., the computing device 2400, components of the computing device 2400, devices coupled to the computing device, etc.), temperatures of an environment (e.g., a data center that includes, is controlled by, or otherwise associated with the computing device 2400), and so on. The temperature detection device 2426 may include one or more temperature sensors. Different temperature sensors of the temperature detection device 2426 may have different locations within and around the computing device 2400. A temperature sensor may generate data (e.g., digital data) representing detected temperatures and provide the data to another device, e.g., to the temperature regulation device 2428, the processing device 2402, the memory 2404, etc. In some embodiments, a temperature sensor of the temperature detection device 2426 may be turned on or off, e.g., by the processing device 2402 or an external system. The temperature sensor detects temperatures when it is on and does not detect temperatures when it is off. In other embodiments, a temperature sensor of the temperature detection device 2426 may detect temperatures continuously and automatically or detect temperatures at predefined times or at times triggered by an event associated with the computing device 2400 or any components therein.

The temperature regulation device 2428 may include any device configured to change (e.g., decrease) temperatures, e.g., based on one or more target temperatures and/or based on temperature measurements performed by the temperature detection device 2426. A target temperature may be a preferred temperature. A target temperature may depend on a setting in which the computing device 2400 operates. In some embodiments, the target temperature may be 200 Kelvin degrees or lower. In some embodiments, the target temperature may be 20 Kelvin degrees or lower, or 5 Kelvin degrees or lower. Target temperatures for different objects and different environments of, or associated with, the computing device 2400 can be different. In some embodiments, cooling provided by the temperature regulation device 2428 may be a multi-stage process with temperatures ranging from room temperature to 4K or lower.

In some embodiments, the temperature regulation device 2428 may include one or more cooling devices. Different cooling device may have different locations within and around the computing device 2400. A cooling device of the temperature regulation device 2428 may be associated with one or more temperature sensors of the temperature detection device 2426 and may be configured to operate based on temperatures detected the temperature sensors. For instance, a cooling device may be configured to determine whether a detected ambient temperature is above the target temperature or whether the detected ambient temperature is higher than the target temperature by a predetermined value or determine whether any other temperature-related condition associated with the temperature of the computing device 2400 is satisfied. In response to determining that one or more temperature-related condition associated with the temperature of the computing device 2400 are satisfied (e.g., in response to determining that the detected ambient temperature is above the target temperature), a cooling device may trigger its cooling mechanism and start to decrease the ambient temperature. Otherwise, the cooling device does not trigger any cooling. A cooling device of the temperature regulation device 2428 may operate with various cooling mechanisms, such as evaporation cooling, radiation cooling, conduction cooling, convection cooling, other cooling mechanisms, or any combination thereof. A cooling device of the temperature regulation device 2428 may include a cooling agent, such as a water, oil, liquid nitrogen, liquid helium, etc. In some embodiments, the temperature regulation device 2428 may be, for example, a dilution refrigerator, a helium-3 refrigerator, or a liquid helium refrigerator. In some embodiments, the temperature regulation device 2428 or any portions thereof (e.g., one or more of the individual cooling devices) may be connected to the computing device 2400 in close proximity (e.g., less than about 1 meter) or may be provided in a separate enclosure where a dedicated heat exchanger (e.g., a compressor, a heating, ventilation, and air conditioning (HVAC) system, liquid helium, liquid nitrogen, etc.) may reside.

By maintaining the target temperatures, the energy consumption of the computing device 2400 (or components thereof) can be reduced, while the computing efficiency may be improved. For example, when the computing device 2400 (or components thereof) operates at lower temperatures, energy dissipation (e.g., heat dissipation) may be reduced. Further, energy consumed by semiconductor components (e.g., energy needed for switching transistors of any of the components of the computing device 2400) can also be reduced. Various semiconductor materials may have lower resistivity and/or higher mobility at lower temperatures. That way, the electrical current per unit supply voltage may be increased by lowering temperatures. Conversely, for the same current that would be needed, the supply voltage may be lowered by lowering temperatures. As energy corelates to the supply voltage, the energy consumption of the semiconductor components may lower too. In some implementations, the energy savings due to reducing heat dissipation and reducing energy consumed by semiconductor components of the computing device or components thereof may outweigh (sometimes significantly outweigh) the costs associated with energy needed for cooling.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

FIG. 11 is a block diagram of an example processing device 2500 that may include one or more components including IC structures with elongated vertical structures of channel materials in accordance with any of the embodiments disclosed herein. For example, any suitable ones of the components of the processing device 2500 may include a die (e.g., the die 2002 of FIG. 7) having one or more IC structures with elongated vertical structures of channel materials as described herein. Any one or more of the components of the processing device 2500 may include, or be included in, an IC device assembly 2300 (FIG. 9). Any one or more of the components of the processing device 2500 may include, or be included in, an IC package 2200 of FIG. 8 or an IC device assembly 2300 of FIG. 9. Any one or more of the components of the processing device 2500 may include, or be included in, a computing device 2400 of FIG. 10; for example, the processing device 2500 may be the processing device 2402 of the computing device 2400.

A number of components are illustrated in FIG. 11 as included in the processing device 2500, but any one or more of these components may be omitted or duplicated, as suitable for the application. In some embodiments, some or all of the components included in the processing device 2500 may be attached to one or more motherboards. In some embodiments, some or all of these components are fabricated on a single SoC die or coupled to a single support structure, e.g., to a single carrier substrate.

Additionally, in various embodiments, the processing device 2500 may not include one or more of the components illustrated in FIG. 11, but the processing device 2500 may include interface circuitry for coupling to the one or more components. For example, the processing device 2500 may not include a memory 2504, but may include display device interface circuitry (e.g., a connector and driver circuitry) to which a memory 2504 may be coupled.

The processing device 2500 may include logic circuitry 2502 (e.g., one or more circuits configured to implement logic/compute functionality). Examples of such circuits include ICs implementing one or more of input/output (I/O) functions, arithmetic operations, pipelining of data, etc.

In some embodiments, the logic circuitry 2502 may include one or more circuits responsible for read/write operations with respect to the data stored in the memory 2504. To that end, the logic circuitry 2502 may include one or more I/O ICs configured to control access to data stored in the memory 2504.

In some embodiments, the logic circuitry 2502 may include one or more high-performance compute dies, configured to perform various operations with respect to data stored in the memory 2504 (e.g., arithmetic and logic operations, pipelining of data from one or more memory dies of the memory 2504, and possibly also data from external devices/chips). In some embodiments, the logic circuitry 2502 may be configured to only control I/O access to data but not perform any operations on the data. In some embodiments, the logic circuitry 2502 may implement ICs configured to implement I/O control of data stored in the memory 2504, assemble data from the memory 2504 for transport (e.g., transport over a central bus) to devices/chips that are either internal or external to the processing device 2500, etc. In some embodiments, the logic circuitry 2502 may not be configured to perform any operations on the data besides I/O and assembling for transport to the memory 2504.

The processing device 2500 may include a memory 2504, which may include one or more ICs configure to implement memory circuitry (e.g., ICs implementing one or more of memory devices, memory arrays, control logic configured to control the memory devices and arrays, etc.). In some embodiments, the memory 2504 may be implemented substantially as described above with reference to the memory 2404 (FIG. 10). In some embodiments, the memory 2504 may be a designated device configured to provide storage functionality for the components of the processing device 2500 (e.g., local), while the memory 1604 may be configured to provide system-level storage functionality for the entire computing device 2400 (e.g., global). In some embodiments, the memory 2504 may include memory that shares a die with the logic circuitry 2502. In some embodiments, the memory 2504 may include one or more IC structures with elongated vertical structures of channel materials.

In some embodiments, the memory 2504 may include a flat memory (also sometimes referred to as a “flat hierarchy memory” or a “linear memory”) and, therefore, may also be referred to as a “basin memory.” As known in the art, a flat memory or a linear memory refers to a memory addressing paradigm in which memory may appear to the program as a single contiguous address space, where a processor can directly and linearly address all of the available memory locations without having to resort to memory segmentation or paging schemes. Thus, the memory implemented in the memory 2504 may be a memory that is not divided into hierarchical layer or levels in terms of access of its data.

In some embodiments, the memory 2504 may include a hierarchical memory. In this context, hierarchical memory refers to the concept of computer architecture where computer storage is separated into a hierarchy based on features of memory such as response time, complexity, capacity, performance, and controlling technology. Designing for high performance may require considering the restrictions of the memory hierarchy, e.g., the size and capabilities of each component. With hierarchical memory, each of the various memory components can be viewed as part of a hierarchy of memories (m₁, m₂, . . . , mₙ) in which each member mi is typically smaller and faster than the next highest member mᵢ₊₁ of the hierarchy. To limit waiting by higher levels, a lower level of a hierarchical memory structure may respond by filling a buffer and then signaling for activating the transfer. For example, in some embodiments, the hierarchical memory implemented in the memory 2504 may be separated into four major storage levels: 1) internal storage (e.g., processor registers and cache), 2) main memory (e.g., the system RAM and controller cards), and 3) on-line mass storage (e.g., secondary storage), and 4) off-line bulk storage (e.g., tertiary, and off-line storage). However, as the number of levels in the memory hierarchy and the performance at each level has increased over time and is likely to continue to increase in the future, this example hierarchical division provides only one non-limiting example of how the memory 2504 may be arranged.

The processing device 2500 may include a communication device 2506, which may be implemented substantially as described above with reference to the communication chip 2406 (FIG. 10). In some embodiments, the communication device 2506 may be a designated device configured to provide communication functionality for the components of the processing device 2500 (e.g., local), while the communication chip 2406 may be configured to provide system-level communication functionality for the entire computing device 2400 (e.g., global).

The processing device 2500 may include interconnects 2508, which may include any element or device that includes an electrically conductive material for providing electrical connectivity to one or more components of, or associated with, a processing device 2500 or/and between various such components. Examples of the interconnects 2508 include conductive lines/wires (also sometimes referred to as “lines” or “metal lines” or “trenches”) and conductive vias (also sometimes referred to as “vias” or “metal vias”), metallization stacks, redistribution layers, MIM structures, etc.

The processing device 2500 may include a temperature detection device 2510 which may be implemented substantially as described above with reference to the temperature detection device 2426 of FIG. 10 but configured to determine temperatures on a more local scale, e.g., of the processing device 2500 of components thereof. In some embodiments, the temperature detection device 2510 may be a designated device configured to provide temperature detection functionality for the components of the processing device 2500 (e.g., local), while the temperature detection device 2426 may be configured to provide system-level temperature detection functionality for the entire computing device 2400 (e.g., global).

The processing device 2500 may include a temperature regulation device 2512 which may be implemented substantially as described above with reference to the temperature regulation device 2428 of FIG. 10 but configured to regulate temperatures on a more local scale, e.g., of the processing device 2500 of components thereof. In some embodiments, the temperature regulation device 2512 may be a designated device configured to provide temperature regulation functionality for the components of the processing device 2500 (e.g., local), while the temperature regulation device 2428 may be configured to provide system-level temperature regulation functionality for the entire computing device 2400 (e.g., global).

The processing device 2500 may include a battery/power circuitry 2514 which may be implemented substantially as described above with reference to the battery/power circuitry 2410 of FIG. 10. In some embodiments, the battery/power circuitry 2514 may be a designated device configured to provide battery/power functionality for the components of the processing device 2500 (e.g., local), while the battery/power circuitry 2410 may be configured to provide system-level battery/power functionality for the entire computing device 2400 (e.g., global).

The processing device 2500 may include a hardware security device 2516 which may be implemented substantially as described above with reference to the security interface device 2424 of FIG. 10. In some embodiments, the hardware security device 2516 may be a physical computing device configured to safeguard and manage digital keys, perform encryption and decryption functions for digital signatures, authentication, and other cryptographic functions. In some embodiments, the hardware security device 2516 may include one or more secure cryptoprocessors chips.

The following paragraphs provide various examples of the embodiments disclosed herein.

Example 1 provides an IC structure that includes a substrate (or, more generally, a support structure such as a substrate, a wafer, a die, or a chip), and a pillar of a semiconductor material extending away from the substrate, substantially perpendicular to the substrate, where, in a cross-section of the pillar along a plane perpendicular to the substrate, the pillar tapers (e.g., the width of the pillar gradually decreases) away from the substrate (e.g., the pillar includes a first end and an opposite second end, where the first end is wider than the second end and is closer to the substrate than the second end).

Example 2 provides the IC structure according to example 1, where the semiconductor material of the pillar is a substantially monocrystalline/single-crystalline semiconductor material.

Example 3 provides the IC structure according to examples 1 or 2, where an average grain size of the semiconductor material of the pillar is at least about 1 millimeter.

Example 4 provides the IC structure according to example 1, where the semiconductor material of the pillar includes at least one of a polycrystalline semiconductor material, a polymorphous semiconductor material, or an amorphous semiconductor material.

Example 5 provides the IC structure according to examples 1 or 4, where an average grain size of the semiconductor material of the pillar is below 1 millimeter.

Example 6 provides the IC structure according to any one of the preceding examples, where, in the cross-section of the pillar along the plane perpendicular to the substrate, a sidewall of the pillar has a portion that is at an angle less than about 8 degrees with respect to a line perpendicular to the substrate.

Example 7 provides the IC structure according to any one of examples 1-6, where: the pillar has a first section and a second section, one of the first section and the second section is closer to the substrate than another one of the first section and the second section, a height of the first section is greater than a height of the second section, and, in the cross-section of the pillar along the plane perpendicular to the substrate, a change in width of the pillar per unit height of the pillar is greater for the first section than for the second section.

Example 8 provides the IC structure according to any one of examples 1-6, where: the pillar has a first section and a second section, one of the first section and the second section is closer to the substrate than another one of the first section and the second section, a height of the second section is greater than a height of the first section, and, in the cross-section of the pillar along the plane perpendicular to the substrate, a change in width of the pillar per unit height of the pillar is greater for the first section than for the second section.

Example 9 provides the IC structure according to any one of the preceding examples, where, in the cross-section of the pillar along the plane perpendicular to the substrate, at least a portion of a sidewall of the pillar has an undulating profile.

Example 10 provides the IC structure according to any one of examples 1-9, further including a gate insulator on one or more sidewalls of the pillar; and a conductive material wrapping around at least a portion of the gate insulator.

Example 11 provides the IC structure according to any one of examples 1-9, further including a gate insulator on one or more sidewalls of the pillar; and alternating layers of a conductive material and an insulator material extending substantially parallel to the substrate and at least partially wrapping around different sections of the pillar.

Example 12 provides an IC structure that includes a support structure, e.g., a substrate; one or more materials over the substrate; an opening extending through the one or more materials to the substrate, where a portion of the substrate is a bottom of the opening; and a semiconductor material in the opening, where a crystal lattice orientation of the semiconductor material is substantially same as a crystal lattice orientation of the portion of the substrate at the bottom of the opening (e.g., where a grain orientation of a majority of grains of the semiconductor material is substantially same as a grain orientation of a majority of grains of the portion of the substrate at the bottom of the opening).

Example 13 provides the IC structure according to example 12, where the crystal lattice orientation of the semiconductor material is a crystal lattice orientation of at least 80% of the semiconductor material.

Example 14 provides the IC structure according to examples 12 or 13, where an average grain size of grains of the semiconductor material is at least about 1 millimeter.

Example 15 provides the IC structure according to any one of examples 12-14, where the semiconductor material is a substantially monocrystalline semiconductor material.

Example 16 provides the IC structure according to any one of examples 12-15, where: the portion of the substrate is a first portion, the substrate further includes a second portion, different from the first portion, and a crystal lattice orientation of the second portion is different from the crystal lattice orientation of the first portion (e.g., a grain orientation of a majority of grains of the second portion is different from the grain orientation of the majority of grains of the first portion).

Example 17 provides the IC structure according to any one of examples 12-16, further including a gate insulator on sidewalls of the opening; and the one or more materials include a conductive material wrapping around at least a portion of the gate insulator.

Example 18 provides the IC structure according to any one of examples 12-16, further including a gate insulator on sidewalls of the opening; and the one or more materials include alternating layers of a conductive material and an insulator material extending substantially parallel to the substrate and at least partially wrapping around different section of the opening.

Example 19 provides a method of fabricating an IC structure, the method including patterning a layer of a semiconductor material to form a pillar of the semiconductor material; depositing a gate insulator on sidewalls of the pillar; and depositing alternating layers of an insulator material and a conductive material around the pillar, where the alternating layers are substantially perpendicular to a longitudinal axis of the pillar.

Example 20 provides the method according to example 19, where patterning the layer of the semiconductor material includes etching the semiconductor material using an ALE technique in alternation with using a non-ALE technique.

Example 21 provides an IC package, including an IC die, including an IC structure; and a further component, coupled to the IC die, where the IC structure is an IC structure according to any one of the preceding examples.

Example 22 provides the IC package according to example 21, where the further component is one of a package substrate, an interposer, or a further IC die.

Example 23 provides an electronic device, including a carrier substrate; and one or more of the IC structures according to any one of the preceding examples and/or the IC package according to any one of the preceding claims, coupled to the carrier substrate.

Example 24 provides the electronic device according to example 23, where the carrier substrate is a motherboard.

Example 25 provides the electronic device according to example 23, where the carrier substrate is a PCB.

Example 26 provides the electronic device according to any one of examples 23-25, where the electronic device is a wearable electronic device (e.g., a smart watch) or handheld electronic device (e.g., a mobile phone).

Example 27 provides the electronic device according to any one of examples 23-26, where the electronic device further includes one or more communication chips and an antenna.

Example 28 provides the electronic device according to any one of examples 23-27, where the electronic device is memory device.

Example 29 provides the electronic device according to any one of examples 23-27, where the electronic device is one of an RF transceiver, a switch, a power amplifier, a low-noise amplifier, a filter, a filter bank, a duplexer, an upconverter, or a downconverter of an RF communications device, e.g., of an RF transceiver.

Example 30 provides the electronic device according to any one of examples 23-27, where the electronic device is a computing device.

Example 31 provides the electronic device according to any one of examples 23-30, where the electronic device is included in a base station of a wireless communication system.

Example 32 provides the electronic device according to any one of examples 23-30, where the electronic device is included in a user equipment device (i.e., a mobile device) of a wireless communication system.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) structure, comprising:
a substrate; and
a pillar of a semiconductor material extending away from the substrate,
wherein, in a cross-section of the pillar along a plane perpendicular to the substrate, the pillar tapers away from the substrate.

2. The IC structure according to claim 1, wherein the semiconductor material is a substantially monocrystalline semiconductor material.

3. The IC structure according to claim 1, wherein an average grain size of the semiconductor material is at least about 1 millimeter.

4. The IC structure according to claim 1, wherein the semiconductor material includes at least one of a polycrystalline semiconductor material, a polymorphous semiconductor material, or an amorphous semiconductor material.

5. The IC structure according to claim 1, wherein an average grain size of the semiconductor material is below about 0.5 millimeter.

6. The IC structure according to claim 1, wherein, in the cross-section of the pillar along the plane perpendicular to the substrate, a sidewall of the pillar has a portion that is at an angle less than about 8 degrees with respect to a line perpendicular to the substrate.

7. The IC structure according to claim 1, wherein:
the pillar has a first section and a second section,
one of the first section and the second section is closer to the substrate than another one of the first section and the second section,
a height of the first section is greater than a height of the second section, and,
in the cross-section of the pillar along the plane perpendicular to the substrate, a change in width of the pillar per unit height of the pillar is greater for the first section than for the second section.

8. The IC structure according to claim 1, wherein:
the pillar has a first section and a second section,
one of the first section and the second section is closer to the substrate than another one of the first section and the second section,
a height of the second section is greater than a height of the first section, and,
in the cross-section of the pillar along the plane perpendicular to the substrate, a change in width of the pillar per unit height of the pillar is greater for the first section than for the second section.

9. The IC structure according to claim 1, wherein, in the cross-section of the pillar along the plane perpendicular to the substrate, at least a portion of a sidewall of the pillar has an undulating profile.

10. The IC structure according to claim 1, further comprising:
a gate insulator on one or more sidewalls of the pillar; and
a conductive material wrapping around at least a portion of the gate insulator.

11. The IC structure according to claim 1, further comprising:
a gate insulator on one or more sidewalls of the pillar; and
alternating layers of a conductive material and an insulator material extending substantially parallel to the substrate and at least partially wrapping around different sections of the pillar.

12. An integrated circuit (IC) structure, comprising:
a substrate;
one or more materials over the substrate;
an opening extending through the one or more materials to the substrate, wherein a portion of the substrate is a bottom of the opening; and
a semiconductor material in the opening, wherein a crystal lattice orientation of the semiconductor material is substantially same as a crystal lattice orientation of the portion of the substrate at the bottom of the opening.

13. The IC structure according to claim 12, wherein the crystal lattice orientation of the semiconductor material is a crystal lattice orientation of at least 80% of the semiconductor material.

14. The IC structure according to claim 12, wherein an average grain size of grains of the semiconductor material is at least about 1 millimeter.

15. The IC structure according to claim 12, wherein the semiconductor material is a substantially monocrystalline semiconductor material.

16. The IC structure according to claim 12, wherein:
the portion of the substrate is a first portion,
the substrate further includes a second portion, and
a crystal lattice orientation of the second portion is different from the crystal lattice orientation of the first portion.

17. The IC structure according to claim 12, further comprising:
a gate insulator on sidewalls of the opening; and
the one or more materials include a conductive material wrapping around at least a portion of the gate insulator.

18. The IC structure according to claim 12, further comprising:
a gate insulator on sidewalls of the opening; and
the one or more materials include alternating layers of a conductive material and an insulator material extending substantially parallel to the substrate and at least partially wrapping around different section of the opening.

19. A method of fabricating an integrated circuit (IC) structure, the method comprising:
patterning a layer of a semiconductor material to form a pillar of the semiconductor material;
depositing a gate insulator on sidewalls of the pillar; and
depositing alternating layers of an insulator material and a conductive material around the pillar, wherein the alternating layers are substantially perpendicular to a longitudinal axis of the pillar.

20. The method according to claim 19, wherein patterning the layer of the semiconductor material includes etching the semiconductor material using an atomic layer etch (ALE) technique in alternation with using a non-ALE technique.
